(19) United States
(12) Patent Application Publication
(10) Pub. No.: US 2019/0371989 A1
(43) Pub. Date: Dec. 5, 2019

(54) METHOD OF MANUFACTURING A LEAD FRAME

(71) Applicant: Lumileds LLC, San Jose, CA (US)

(72) Inventors: Yuan XIE, Aachen (DE); Jürgen MERTENS, Wuerselen (DE); Sze Kuang LEE, Bayan Lepas (MY); Nan CHEN, Winchester, MA (US)

(73) Assignee: Lumileds LLC, San Jose, CA (US)

(21) Appl. No.: 16/348,146

(22) PCT Filed: Nov. 6, 2017
(86) PCT No.: PCT/EP2017/078293

§ 371 Date: May 7, 2019

(30) Foreign Application Priority Data
Nov. 11, 2016 (CN) PCT/CN2016/105450
Dec. 12, 2016 (EP) 16203504.2

(51) Int. Cl. H01L 33/62; H01L 21/48; H01L 23/495; H01L 33/64

(52) U.S. Cl. CPC H01L 33/62; H01L 33/647; H01L 23/49541; H01L 21/4842

(57) ABSTRACT

A method of manufacturing a lead frame, includes preparing a stamping arrangement to stamp a lead frame comprising a plurality of electrode contact regions, wherein complementary contact regions are separated by an initial gap width; and a number of connecting bars, wherein a connecting bar extends between regions of the lead frame; using the stamping arrangement to stamp the lead frame; and deforming at least one connecting bar of the stamped lead frame to reduce the gap width between complementary contact regions to a final gap width. Further described is a lead frame comprising a plurality of LED electrode contact regions, with a gap width of at most 250 μm between complementary contact regions after the deformation step. The invention further describes an LED lighting device comprising such a lead frame and at least one LED die package mounted onto complementary electrode contact regions of the lead frame.

### FIELD OF THE INVENTION

The invention describes a method of manufacturing a lead frame.

### BACKGROUND OF THE INVENTION

In the manufacture of light-emitting diode (LED) lighting devices, one approach is to mount an LED die or wafer-level package onto a lead frame or metal carrier. The lead frame comprises contact regions that make electrical contact with the anode and cathode of an LED die, and a voltage source can be connected across the LED by means of the electrode contact regions. The lead frame also acts as a primary heat spreader, since it is directly connected to the LED package. Advances in LED chip technology have led to very small die size with favourably high light output. The small die size requires a small gap between the anode and cathode contact regions of the lead frame or carrier. During operation of an LED, the anode and cathode become hot so that any contact areas to which the die is mounted are subject to thermal deformation. U.S. Pat. No. 4,797,726 describes a method of protecting a semiconductor chip from such thermal stress.

A lead frame is effectively a frame that holds a plurality of leads in place. The leads are the contact regions to which electrical components will later be soldered. The “frame” itself may be entirely or partially discarded by cutting away any unnecessary areas after the electrical components have been mounted to the leads. A lead frame is generally stamped or punched from a piece of sheet metal or a sheet metal strip, using a stamping press with an appropriately shaped stamping tool and corresponding die. It is a challenge to manufacture lead frames for very small LED die packages, since the gap between anode and cathode may comprise only a fraction of a millimetre. For example, LED die packages with an anode-cathode clearance of only 150 μm-250 μm are currently being manufactured, and this clearance may be expected to decrease further as the technology advances. However, there is a limit to the smallest clearance that can be achieved by a conventional stamping tool, particularly since the lead frame can have a thickness in millimetre range in order to be able to effectively transport the heat dissipated by an LED. For example, a practicable sheet metal thickness may lie in the range 0.5-3.0 mm in order for the stamped lead frame to function satisfactorily as a heat spreader. Generally, a conventional stamping tool is designed to stamp through sheet metal so that the space between adjacent regions is no less than the thickness of the sheet metal. In other words, the ratio of sheet thickness to the smallest achievable gap is 1:1, so that the gap width achievable by a conventional stamping press is too wide for the LED die packages mentioned above. This constraint arises from the need to ensure that the stamping procedure can be performed without interruption for an essentially unlimited number of times.

This problem can be addressed by developing a stamping press that can achieve the desired narrow clearance between electrode contact regions. However, re-design of a stamping press is associated with significant expense, particular since the gap between electrode contact regions must be very precise and uniform. Special tooling modifications to achieve small gap widths are therefore generally limited to the production of lead frame prototypes. Another way of dealing with the problem may be to stamp a lead frame with a large region that will later be sub-divided by cutting or milling into two, four or more individual electrode contact regions. A cutting or milling step can use finer tools that are capable of cutting or forming the desired narrow slit or gap over which the small LED dies can later be mounted. However, owing to the level of precision required in forming the gap or slit between contact regions, such additional tools and the additional tooling step add significantly to the overall cost of the LED devices.

Therefore, it is an object of the invention to provide a more economical way of manufacturing a lead frame.

### SUMMARY OF THE INVENTION

The object of the invention is achieved by the method of claim 1 of manufacturing a lead frame and by the lead frame of claim 12.

According to the invention, the lead frame manufacturing method comprises the steps of preparing a stamping tool to stamp a lead frame from sheet metal, so that the lead frame includes a plurality of LED electrode contact regions or tiles, wherein complementary anode/cathode contact regions are separated by an initial gap width; and also a number of narrow connecting bars, bridges or fillets, wherein a connecting bar extends between two regions of the lead frame. The method further comprises a step of using the stamping tool to stamp the lead frame; and subsequently deforming at least one connecting bar of the stamped lead frame to reduce the gap width between complementary contact regions to a final gap width.

Of course, the tool preparation step need only be carried out once. After preparing the tool of a conventional stamping press to stamp the desired lead frame shape, the tool can be used repeatedly to stamp lead frames from sheet metal, for example from a continuous band of sheet metal fed from a roll into the stamping press at an appropriate rate. Such a stamping press can be prepared to stamp or punch one or more lead frames from a sheet. Equally, a stamping press can stamp a series of lead frames in a continuous strip of sheet metal.

During stamping, portions of the sheet metal are punched out, leaving a desired arrangement of interconnected regions, most of which serve a specific purpose in the end device. Specifically, the stamped lead frame will comprise several electrode contact regions or “tiles” and any number of connecting bars. Initially, the electrode contact regions are separated by gap widths that are easily achievable by the conventional stamping press. As indicated above, such gap widths are too large for use with very small LED die packages that require a clearance of only a few hundred μm or less. The deformation step of the inventive method is carried out on the stamped lead frame to deform at least one connecting bar of the stamped lead frame, with the result that the gap width between complementary contact regions or tiles is reduced to the desired clearance width. An advantage of the inventive method is that a final gap width or clearance of only 250 μm or less can easily be achieved, even if the initial stamped gap width was the same as the sheet metal thickness, even for relatively thick sheet metal. Another advantage of the inventive method is that the lead frame can be produced with relatively little effort and at low cost.

According to the invention, the lead frame achieved by the inventive manufacturing method comprises a plurality of LED electrode contact regions, wherein complementary contact regions are separated by a gap width of at most 250 μm after the deformation step. The inventive lead frame is cheap to manufacture and can be used as a carrier for very small LED die packages.

An LED lighting device comprising a lead frame according to the invention can therefore comprise one or more LED die packages mounted onto complementary anode and cathode contact regions of the lead frame, and the LED die packages can have an electrode clearance of only 250 μm or less. The LED lighting device which can be achieved using the inventive lead frame can therefore be favourably economical to manufacture, since there is no need for expensive tooling solutions in the preparation of the lead frames for the required narrow electrode clearance.

The dependent claims and the following description disclose particularly advantageous embodiments and features of the invention. Features of the embodiments may be combined as appropriate. Features described in the context of one claim category can apply equally to another claim category.

A stamped lead frame generally includes various areas that will later be discarded. The reason for this is to simplify the stamping process and also more importantly to simplify the component mounting process. For example, LED die packages can be mounted to the electrode regions of a continuous series of lead frames in a soldering step. In this way, hundreds of devices can be prepared in an efficient and cost-effective manner. After a soldering step, the individual devices can be cut from the lead frame strip or sheet. For this reason, the stamping tool is generally prepared to include such “superfluous” or “waste” regions in the stamped lead frame, and the useful regions (such as the electrode contact regions) are initially held in place by connecting bars, which may also be later cut from the lead frame and discarded or recycled. The connecting bars may form an outer frame around the tiles, or can extend between an outer frame and the tiles.

In the inventive method, the electrode contact regions or tiles are initially stamped so that they are separated by a relatively large gap, and are held in place within the frame by the connecting bars. In one preferred embodiment of the invention, the stamping tool is prepared to stamp one or more connecting bars extending from a tile to a side bar of the lead frame. Preferably, such a connecting bar extends diagonally from a tile to a side bar of the lead frame. A connecting bar is preferably narrow so that it can be deformed with relatively little effort. To this end, the stamping tool is preferably prepared to stamp a connecting bar that has a width corresponding essentially to the thickness of the sheet metal. A connecting bar width in the millimetre range is easily achievable by most conventional stamping press arrangements that handle that thickness of sheet metal.

In one preferred embodiment of the invention, the step of deforming a connecting bar comprises bending or displacing the connecting bar within the plane of the lead frame, which has the effect of adjusting the angle of the connecting bar. In this way, the tile at the end of this connecting bar will be displaced towards the other tile(s), thereby effectively reducing the gap or clearance between those tiles.

In another preferred embodiment of the invention, the step of deforming a connecting bar comprises forcing a short length of the connecting bar out of the plane of the lead frame. This results in a small “arch” formed from a section of that connecting bar. The deformation only involves a geometrical alteration but does not involve stretching, so that an arch, extending out of the plane of the lead frame, effectively shortens the length of the connecting bar. In this way, any electrode contact regions linked by this connecting bar will be displaced towards each other, effectively reducing the gap or clearance between them.

The inventive method provides a simple and straightforward way of achieving a very narrow clearance between electrode contact regions. However, care must be taken to ensure that a gap between electrode contact regions is uniform over its entire length. Furthermore, the final gap width or clearance to be achieved also depends on the basis of thermal requirements of the type of LED die to be mounted over complementary contact regions of the lead frame. The final gap width should therefore not be excessively narrow. A minimum gap width of about 50 μm may be sufficient to avoid solder from “bridging” the gap and causing a short circuit. To this end, in a preferred embodiment of the invention, the method includes a step of inserting a gauge in the space between complementary contact regions to limit the extent of deformation of a connecting bar. The gauge preferably has the same width as the desired clearance, and can be realised as a shim or similar device. The gauge can be held in place while the deformation step is being carried out. These techniques ensure that the gap is narrow and that the vertical faces of the opposing tiles are parallel over the entire length of the gap.

The deformation step is performed after stamping and prior to soldering. Between these stages, the tiles should preferably not depart from their new positions.

Therefore, in a further preferred embodiment of the invention, the deformation step is followed by a stabilizing step in which the stresses arising during the deformation step are reduced and/or in which the positions of the electrode contact regions are spatially fixed. For example, an annealing procedure can be carried out, in which the lead frame is heated and cooled. Annealing can be carried out during the deformation step and/or after the deformation step. Alternatively or in addition, a vertical deformation of the connecting bars (out of the plane of the lead frame) can follow their horizontal deformation (within the plane of the lead frame) to fix the positions of the electrode contact regions. Another way of fixing the electrode contact regions in place might be by applying an over-moulding technique in which, after the deformation step, the lead frame is aligned in a moulding tool and spatially fixed by plastic over-moulding. For example, plastic over-moulding applied on either side of the lead frame can hold the electrode contact regions in place. A moulding tool is preferably shaped to hold at least the tiles in place while applying the over-mould plastic material. The plastic material should be electrically isolating and should have favourable thermal characteristics since a soldering step will follow. Stabilizing the electrode contact regions by one or more of the above steps will reduce stresses in the connecting bars or bridges and ensure that the lead regions are spatially fixed in place and will not change position.

In a later manufacturing step, one or more LED dies for example surface mount LED dies—can be attached in a reflow soldering process across the narrow slit between the electrode contact regions. This step can be followed by cutting away any waste or superfluous material from the lead frame to remove short circuit connections. The device can then be packaged as required.

Other objects and features of the present invention will become apparent from the following detailed descriptions considered in conjunction with the accompanying drawings. It is to be understood, however, that the drawings are designed solely for the purposes of illustration and not as a definition of the limits of the invention.

### BRIEF DESCRIPTION OF THE DRAWINGS

FIG. 1 shows a first embodiment of a stamped lead frame obtained by the inventive method;

FIG. 2 shows the lead frame of FIG. 1 after a deformation step;

FIG. 3 shows a second embodiment of a stamped lead frame obtained by the inventive method;

FIG. 4 shows the lead frame of FIG. 3 after a deformation step;

FIG. 5 shows a perspective view of the lead frame of FIGS. 3 and 4;

FIG. 6 shows a simplified schematic of a stamping press as used by the inventive method;

FIG. 7 illustrates stages of the inventive method;

FIG. 8 shows part of an LED light-emitting arrangement comprising a lead frame obtained by the inventive method;

FIG. 9 shows a third embodiment of a stamped lead frame obtained by the inventive method;

FIGS. 10 and 11 show the lead frame of FIG. 9 in further manufacturing stages;

FIG. 12 shows an embodiment of the inventive LED lighting device.

In the drawings, like numbers refer to like objects throughout. Objects in the diagrams are not necessarily drawn to scale.

### DETAILED DESCRIPTION OF THE EMBODIMENTS

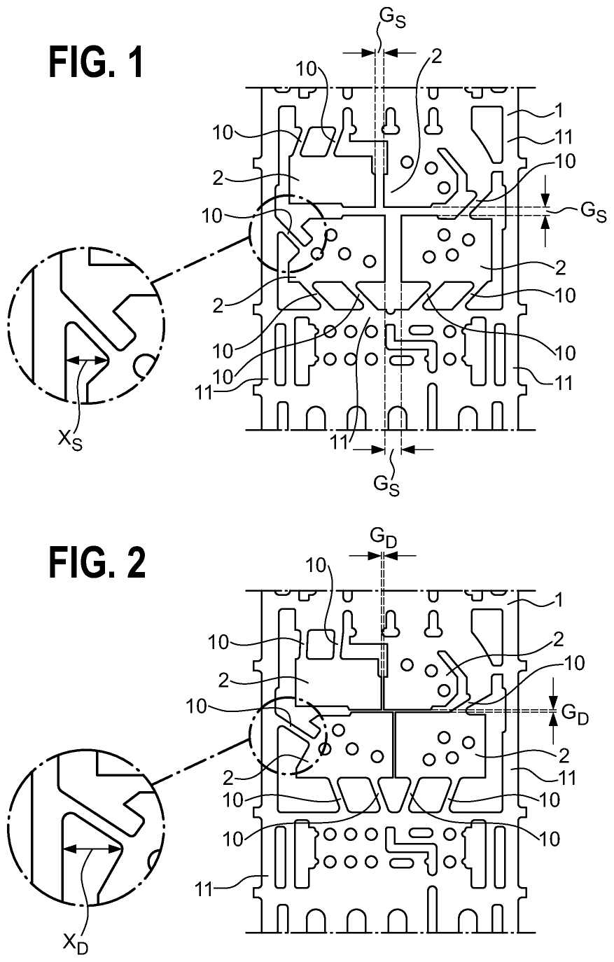

FIG. 1 shows a first embodiment of a lead frame 1, obtained by stamping or punching using a tool that has been prepared to stamp the lead frame shape shown in the diagram. The tool can be used to repeatedly stamp lead frames from a strip of sheet metal that is fed through the tool. During stamping, portions of the sheet metal strip are punched out, leaving a desired arrangement of regions, each of which generally serves a specific purpose later on. In the diagram, the lead frame 1 is a portion of a longer strip of stamped lead frames, and shows a relevant portion with four tiles 2 or LED electrode contact regions 2, to which the electrodes of one or more LED die packages will later be soldered. For efficient heat transport from the LEDs during operation, the lead frame 1 generally requires a thickness in the range of about 3.0 mm. As mentioned above, the smallest achievable gap size between portions of a stamped lead frame is limited by the constraints of conventional or standard stamping tools. The gap width Gs between tiles 2 of the stamped lead frame 1 is therefore unfavourably wide. To overcome this constraint, the stamping tool is prepared using the inventive method so that connecting bars 10 are provided between the tiles 2 and the rest of the lead frame 1. The diagram shows four tiles 2, three of which are connected by such connecting bars 10 to the rest of the lead frame 1. These connecting bars 2 are thin and relatively long, so that they can be bent within the plane of the lead frame 1 (i.e. within the plane of the page) with little effort. A connecting bar 10 can be regarded as the hypotenuse of a right triangle, as indicated in the enlarged view, which shows the connecting bar 10 on the left-hand side of the bottom-left tile 2 initially subtending an angle to the side bar of the lead frame 1 so that the longer “virtual” leg has a length X_{S}. Bending this connecting bar 10 sideways within the plane of the lead frame 1 will shorten one leg and lengthen the “virtual” leg, while the length of the hypotenuse (the connecting bar 10) remains fixed.

The result of such a deformation step is shown in FIG. 2. The initial “virtual leg” length X_{S} after stamping has been increased to a longer length X_{D} by deformation. This brings the tile 2 at the end of that connecting bar 10 closer to its neighbouring tiles 2. In FIG. 2, all the tiles 2 connected by connecting bars 10 to the rest of the lead frame 1 have been moved by deforming the connecting bars 10. The short arrows in the diagram indicate the direction of deformation of the connecting bars 10. The top-right tile 2 in the diagram does not require any connecting bars, since it is sufficient to move or displace the other three tiles 2 in the direction of the top-right tile 2. The result of displacing the tiles 2 in this manner, within the plane of the lead frame 1, is to decrease the gap width between tiles 2. After deformation, the gap width G_{D} is significantly smaller than the initial gap width G_{S}. The inventive method can achieve a gap width G_{D} as small as 150 μm, even for a lead frame thickness in the range of 3.0 mm. This opens up the possibility of placing very small surface-mount LED packages across complementary tiles 2 of the lead frame 1, while being able to manufacture the lead frame 1 very economically using a standard stamping tool.

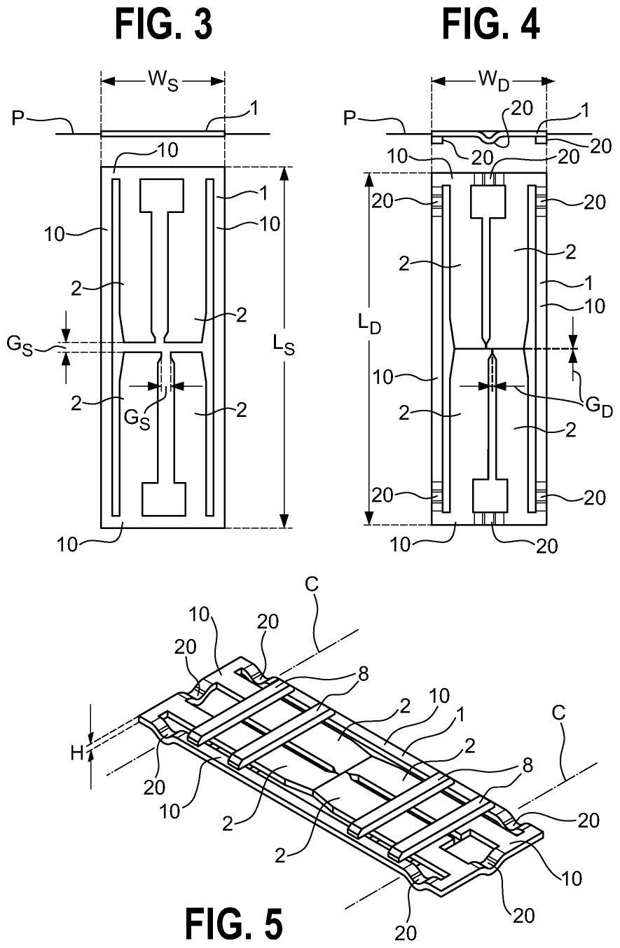

FIG. 3 shows an alternative embodiment of a lead frame 1 stamped from a sheet metal strip. The diagram shows a plan view of the lead frame 1, and an end-face view (in the top part of the diagram). Initially, the stamped lead frame 1 has a width W_{S} and a length L_{S}, and has been stamped to form four elongated tiles 2 and connecting bars 10 extending between the four corners of the rectangular lead frame 1. The tiles 2 will receive the anodes and cathodes of LED packages later on. Like the embodiment described in FIGS. 1 and 2 above, no particular effort need be taken to stamp the lead frame 1 with a small gap width between complementary tiles 2. Initially, the stamped lead frame 1 has an initial gap width G_{S} between complementary tiles 2. The stamped lead frame 1 is then subject to a deformation step. In this embodiment, as shown in FIG. 4, the thin straight sections 10 or connecting bars 10 of the lead frame 1 are bent out of the plane of the lead frame 1. Each bent section appears as an inverted “arch”, as shown in the end-face view (in the top part of the diagram). The plan view in FIG. 4 shows three such sections at the upper region of the lead frame 1, and three such sections in the lower region. A suitable tool can be used to from all six “arches” simultaneously, for example. The result of the deformation step is to shorten the overall width W_{D} and length L_{D} of the lead frame 1, effectively moving the four tiles 2 closer together, so that the resulting gap width G_{D} is shortened correspondingly. The amount by which the gap width is shortened can be determined by using a suitable tool to form suitably dimensioned “arches”. FIG. 5 shows a perspective view of the lead frame 1 described in FIGS. 3 and 4, and clearly indicates the six inverted “arches” formed to achieve the favourably small gap width G_{D}. The diagram also shows over-mould plastic elements 8 attached from above and below the lead frame to the tiles 2 and lead frame side bars in order to hold these together after the lead frame 1 is cut to remove short-circuit connections between the tiles 2. Exemplary cutting lines C are indicated in the diagram. Superfluous material at the outer ends of the lead frame 1 is removed and can be re-cycled.

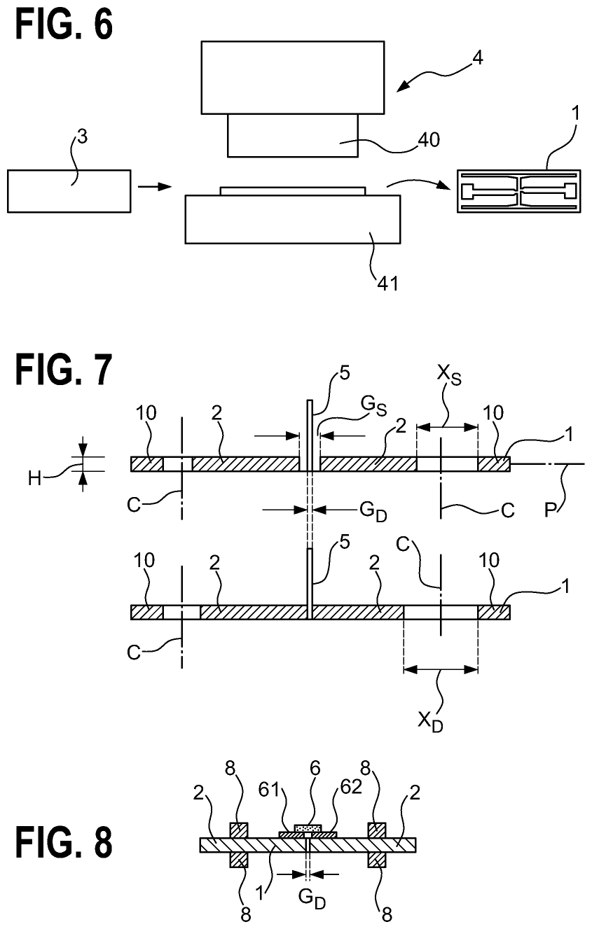

FIG. 6 shows a simplified schematic of a stamping press 4, with a stamping tool 40 prepared to stamp a lead frame as described in FIG. 3. A piece of sheet metal 3 is inserted between the stamping tool 40 and a stamping die 41, and the stamping press 4 is actuated to perform a punching or stamping action. The resulting stamped lead frame 1 is then removed from the press 4. Of course, a continuous strip of sheet metal 3 can be fed into the press, and the resulting lead frame can also be in the form of a continuous strip, as will be known to the skilled person. A separate tool can be used to perform the deformation step, and this can be carried out at the same location, or at a different location as appropriate.

FIG. 7 illustrates a deformation step, and shows a gauge 5 inserted between complementary tiles 2 of a stamped lead frame 1 with thickness H. The gauge 5 can have a width G_{D} in the range of 100-250 μm, corresponding to the desired gap width G_{D} between electrode contact regions of an LED die package. The width G_{S} of the gap is initially quite wide, for example the ratio G_{S}:H can be 1:1 to allow for a low-cost stamping procedure. During the deformation step, for example by bending the connecting bars 10 of FIGS. 1 and 2 within the plane P of the lead frame 1, the gap is reduced to the width G_{D} of the gauge 5. Deformation can involve bending the connecting bars 10 of FIGS. 1 and 2 within the plane P of the lead frame 1. When a connecting bar 10 is regarded as the hypotenuse of a right triangle as explained in FIGS. 1 and 2 above, the initial “virtual leg” length X_{S} after stamping is increased to a longer length X_{D} by deformation. This brings the tile 2 at the end of a connecting bar 10 closer to its neighbouring tile(s), as illustrated in the lower part of the diagram.

Although not shown in this diagram, the deformation step can involve forming “arches” as illustrated in FIGS. 3-5 out of the plane P of the lead frame 1. In either case, the initially wide gap is reduced to a favourably narrow gap with the same width G_{D} as the gauge 5. Using the gauge 5 to control the gap width can ensure that the gap width is not too narrow. The diagram also indicates cutting lines C, indicating the portions of lead frame 1 that will be discarded, for example after over-moulding and soldering.

FIG. 8 shows part of an LED light-emitting arrangement. Here, the anode 61 and cathode 62 of an SMD LED die package 6 are soldered onto complementary tiles 2 of the inventive lead frame 1. The favourably narrow gap width G_{D} between the complementary tiles 2 allows the use of a favourably small SMD LED die package 6. The diagram also shows over-moulded plastic elements 8 that act to hold the tiles 2 in place.

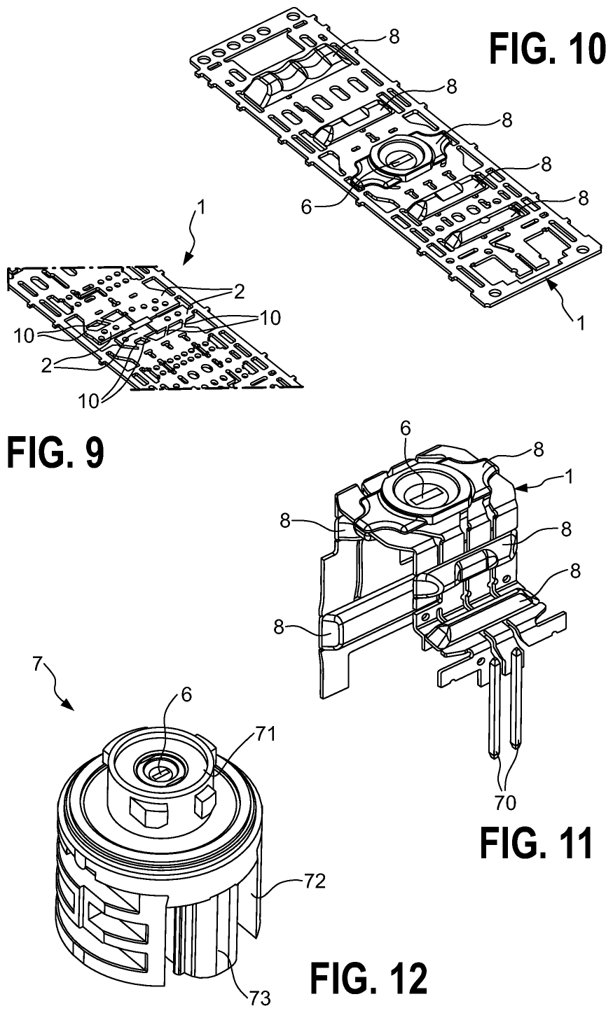

FIG. 9 shows a further embodiment of a lead frame 1, obtained in a similar manner to the lead frame of FIG. 1. The diagrams shows a lead frame with four tiles 2 or LED electrode contact regions 2, to which the electrodes of three LED die packages will later be soldered. The stamping tool used to form the lead frame 1 has left connecting bars 10 between three of the tiles 2 and the rest of the lead frame 1. These connecting bars 2 can be bent within the plane of the lead frame 1 (i.e. within the plane of the page) with little effort. This allows a very narrow gap width between tiles 2, as narrow as 150 μm, even for a lead frame thickness in the range of 3.0 mm. After the lead frame has been prepared in this way, a surface-mount LED package 6 can be mounted across complementary tiles 2 of the lead frame 1.

FIG. 10 indicates over-mould elements 8 arranged to hold various parts of the lead frame together, to provide a window for the LEDs 6, to cover other electronic components mounted on the lead frame 1, and also to act as spacers when the lead frame 1 is incorporated in a lighting device.

FIG. 11 shows a further stage in the manufacture of a lighting device. Here, the lead frame 1 has been cut or trimmed to remove superfluous material, and the remainder has been bent at certain pre-determined locations to achieve a specific shape. Connectors 70 have been welded to positive and negative tabs of the lead frame 1. A final over-moulding step can then be carried out if required. FIG. 12 shows a final stage in the manufacture of the LED lighting device 7, with the lead frame embedded in a unit that comprises both a housing 71 and a heat-sink 72. The housing and/or the heat sink can be made of thermally conductive plastics. The connectors are enclosed in a socket portion 73 which can mate with a corresponding plug connector. The embodiment of the LED lighting device 7 shown in FIG. 12 can be particularly suitable for an automotive LED front lighting application, and can be developed especially for the original equipment manufacturer (OEM) market. The inventive concept provides a compact LED light source enclosed in a lamp unit that can act in a manner similar to conventional lamps for such front lighting applications, so that the lighting device 7 can be easily installed. This embodiment of an LED lighting device does not require an active cooling system or driver box is needed. Due to the precise placement of the LEDs and the over-moulded plastic protection, the inventive lighting device exhibits a long lifetime and a favourable high degree of mechanical strength.

Although the present invention has been disclosed in the form of preferred embodiments and variations thereon, it will be understood that numerous additional modifications and variations could be made thereto without departing from the scope of the invention. For example, the inventive method can be used to provide a lead frame for carrying any electrical device that requires a very narrow clearance between leads.

For the sake of clarity, it is to be understood that the use of “a” or “an” throughout this application does not exclude a plurality, and “comprising” does not exclude other steps or elements.

1. A method of manufacturing a lead frame, comprising:
preparing a stamping arrangement to stamp a lead frame, the lead frame including a plurality of electrode contact regions and a plurality of connecting bars,
wherein complementary contact regions of the plurality of electrode contact regions are separated by an initial gap width; and
wherein a connecting bar extends between regions of the lead frame;
using the stamping arrangement to stamp the lead frame; and
deforming at least one of the nluralitv of connecting bars of the stamped lead frame to reduce the initial gap width between the complementary contact regions to a final gap width.

2. The method according to claim 1, wherein the stamping arrangement is prepared to stamp at least one of the plurality of connecting bars extending from one of the electrode contact regions to a side bar of the lead frame.

3. (The method according to claim 1, wherein one of the plurality of connecting bar extends diagonally fromone of the electrode contact regions to a side bar of the lead frame.

4. The method according to claim 1, wherein deforming theat least one connecting bar comprises bending the at least one connecting bar within the plane of the lead frame.

5. The method according to claim 1, wherein deforming the at least one connecting bar comprises bending a portion of the at least one connecting bar out of the plane of the lead frame to shorten the length of the at least one connecting bar.

6. The method according to claim 1 wherein the stamping arrangement is prepared to stamp at least one connecting bar with a width corresponding to the thickness of the lead frame.

7. The method according to claim 1, comprising inserting a gauge in the gap between complementary contact regions to limit the extent of one of the plurality of connecting bars.

8. The method according to claim 1, wherein the final gap width is determined on the basis of thermal requirements of an LED die package to be mounted over the complementary contact regions of the lead frame.

9. The method according to claim 1, further comprising annealing to fix the final positions of the plurality of electrode contact regions, wherein the annealing happens after the at least one connecting bar is deformed.

10. A method according to claim 1, further comprising over-moulding to fix the final positions of the plurality of electrode contact regions, wherein the over-moulding happens after the at least one connecting bar is deformed.

11. The method according to claim 1, wherein the stamping tool is prepared to achieve the initial gap width that corresponds to the thickness of the stamped lead frame.

12. A lead frame comprising:
a plurality of LED electrode contact regions; and
a plurality of connecting bars, wherein
complementary contact regions of the plurality of LED electrode contact regions are separated by an initial gap width.
one of the plurality of a connecting bars extends between regions of the lead frame,
a stamping arrangement stamps the lead frame.
at least one of the plurality of connecting bare of the stamped lead frame is deformed to reduce the initial map width between complementary contact regions to a final gap width, and
the final gap width at most 250 μm.

13. The lead frame according to claim 12, wherein the final gap width at most 150 μm.

14. An LED lighting device comprising;
a lead frame, the lead frame including
a plurality of LED electrode contact regions; and
a plurality of connecting bars, wherein
complementary contact regions of the plurality of LED electrode contact regions are separated by an initial gap width,
one of the plurality of a connecting bars extends between regions of the lead frame,
a stamping arrangement stamps the lead frame,
at least one of the plurality of connecting bars of the stamped lead frame is deformed to reduce the initial gap width between complementary contact regions to a final gap width, and
at least one LED die package mounted onto the complementary electrode contact regions of the lead frame.

15. The LED lighting device according to claim 14, wherein the LED die package comprises a surface mount LED die package.
